(19) United States
(12) Patent Application Publication
(10) Pub. No.: US 2025/0149252 A1
(43) Pub. Date: May 8, 2025

(54) THIN FILM CAPACITOR AND ELECTRONIC CIRCUIT BOARD HAVING THE SAME

(71) Applicant: TDK Corporation, Tokyo (JP)

(72) Inventors: Daiki ISHII, Tokyo (JP); Mitsuhiro TOMIKAWA, Tokyo (JP); Kenichi YOSHIDA, Tokyo (JP); Takashi KARIYA, Tokyo (JP); Yasunori HARADA, Tokyo (JP); Yoshiaki HAYAMIZU, Tokyo (JP); Miyu HASEGAWA, Tokyo (JP)

(21) Appl. No.: 18/837,696

(22) PCT Filed: Dec. 2, 2022
(86) PCT No.: PCT/JP2022/044516

§ 371 Date: Aug. 12, 2024

Related U.S. Application Data
(60) Provisional application No. 63/310,715, filed on Feb. 16, 2022.

(51) Int. Cl. H01G 4/33; H01G 4/008; H01L 23/00; H05K 1/11; H05K 1/18

(52) U.S. Cl. CPC H01G 4/33; H01G 4/008; H05K 1/112; H05K 1/181; H05K 1/185; H01L 24/08; H01L 24/16; H01L 2224/08113; H01L 2224/16227; H01L 2924/30101; H01L 2924/30107; H05K 2201/10015; H05K 2201/10212

(57) ABSTRACT

To provide a thin film capacitor having a pair of terminal electrodes capable of being disposed on the same plane. A thin film capacitor includes a metal foil having a roughened surface, a dielectric film covering the roughened surface of the metal foil and having an opening partially exposing the metal foil therethrough, an electrode layer contacting the metal foil through the opening, and an electrode layer contacting the dielectric film without contacting the metal foil. An upper surface position of the electrode layer is equal to or lower in height than that of the electrode layer.

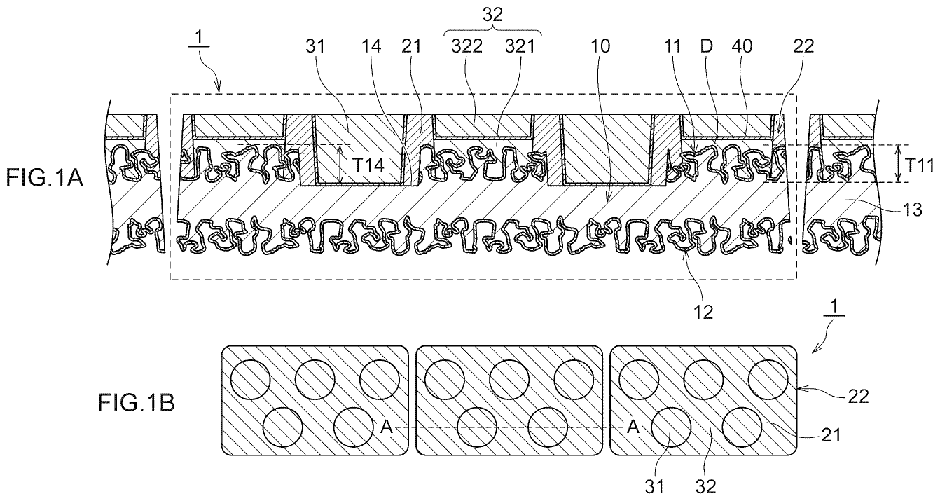

FIG. 1A is a schematic cross-sectional view for explaining the structure of a thin film capacitor 1 according to a first embodiment of the present invention. FIG. 1B is a schematic plan view of the thin film capacitor 1. FIG. 1A illustrates a cross section taken along the line A-A in FIG. 1B.

As illustrated in FIGS. 1A and 1B, the thin film capacitor 1 includes an aluminum foil, a plurality of ring-shaped or polygonal annular insulating resins formed on the upper surface of the aluminum foil, a first terminal electrode formed on the upper surface of the aluminum foil and positioned in a region surrounded by the insulating resin, and a conductive polymer and a second terminal electrode which are formed on the upper surface of the aluminum foil and positioned outside the region surrounded by the insulating resin. In place of the aluminum foil, a metal foil such as a copper foil, a chrome foil, a nickel foil, or a tantalum foil may be used. The surface layer part of the aluminum foil is roughened. The center part of the aluminum foil is not roughened. A dielectric film made of aluminum oxide is formed on the roughened surface of the aluminum foil.

The first terminal electrode is connected to the non-roughened center part of the aluminum foil through a seed layer. The second terminal electrode is connected to the conductive polymer through the seed layer. The seed layer, first terminal electrode, and second terminal electrode are each made of, e.g., a metal material such as copper, nickel, gold, or an alloy or layer structure thereof. In particular, copper is preferably used for the first and second terminal electrodes. The seed layer is preferably made of a material having a barrier function capable of preventing diffusion of copper, having high adhesion to the aluminum foil, insulating resin, and conductive polymer, and causing no damage on the conductive polymer.

The ring-shaped or polygonal annular insulating resin electrically separates the first and second terminal electrodes. In the region surrounded by the insulating resin, the dielectric film made of aluminum oxide is removed. Thus, the first terminal electrode is electrically connected to the aluminum foil. On the other hand, outside the region surrounded by the insulating resin, the dielectric film made of aluminum oxide is not removed. Thus, the second terminal electrode and aluminum foil are insulated from each other. This allows the first and second terminal electrodes to function as a pair of capacitive electrodes facing each other through the dielectric film made of aluminum oxide. The dielectric film is formed on the roughened surface of the aluminum foil, and the surface area of the roughened aluminum foil surface is enlarged, whereby a large capacitance can be obtained.

The aluminum foil has a groove at a part thereof connected with the first terminal electrode. The depth of the groove is equal to or larger than the thickness of the roughened surface layer part. This exposes the non-roughened center part of the aluminum foil at the groove bottom. The center part of the aluminum foil exposed to the groove bottom is flat. The groove bottom contacts the seed layer and insulating resin. Since the groove bottom is flat, voids hardly occur between the aluminum foil and the seed layer and between the aluminum foil and the insulating resin. This enhances adhesion of the first terminal electrode and insulating resin to the aluminum foil. Further, both the first and second terminal electrodes do not protrude from the surface of the insulating resin but are embedded therein. That is, the first and second terminal electrodes each have a damascene structure. In the example illustrated in FIG. 1A, the upper surfaces of the insulating resin, first terminal electrode, and second terminal electrode are flush with one another.

The thin film capacitor 1 can be used as a decoupling capacitor when being embedded in a multilayer substrate. Further, the first terminal electrode is divided into a plurality of parts, so that ESR and ESL can be reduced as compared with when the number of the first terminal electrodes is one. Further, the first and second terminal electrodes each have a damascene structure, so that when the thin film capacitor 1 is embedded in a multilayer substrate, local stress is hardly applied to the thin film capacitor 1. In particular, the roughened surface layer part of the aluminum foil and the dielectric film formed on the surface thereof are present below the second terminal electrode, so that when high stress is applied thereto, a reduction in capacitance and/or a short-circuit failure may occur. However, in the thin film capacitor 1 according to the present embodiment, the upper surface of the second terminal electrode does not protrude, so that it is possible to suppress stress to be applied to the roughened surface layer part of the aluminum foil and the dielectric film.

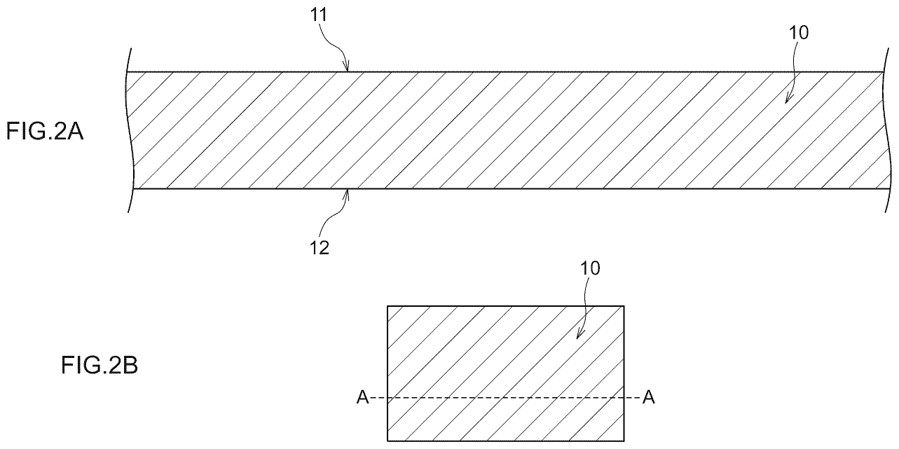

The following describes an example of a manufacturing method for the thin film capacitor 1. FIGS. 2A to 21A are schematic cross-sectional views taken along the line A-A in FIGS. 2B to 21B.

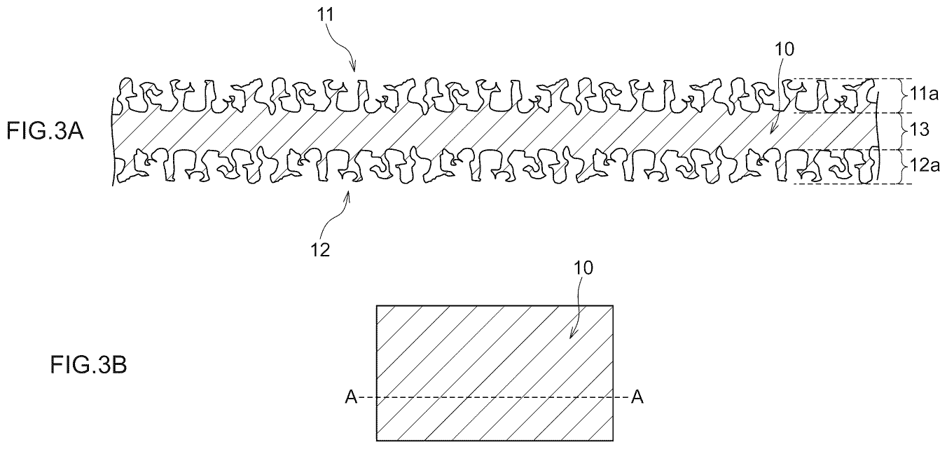

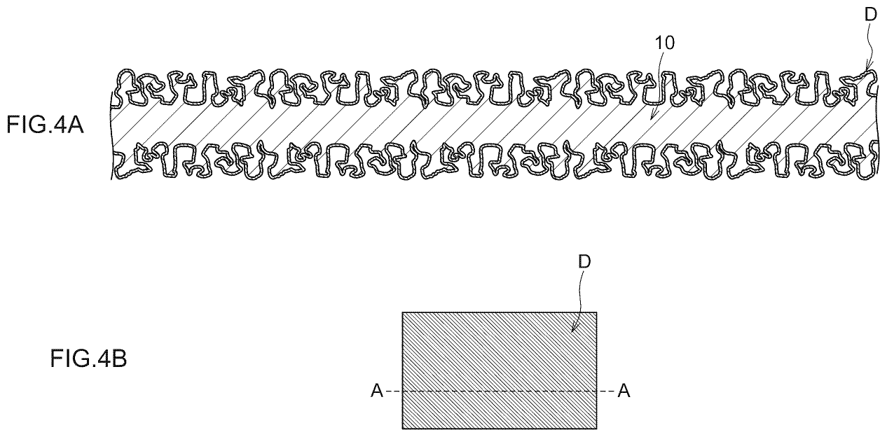

First, an aluminum foil with a thickness of about 50 μm is prepared (FIGS. 2A and 2B), and surfaces of the aluminum foil are roughened by etching (FIGS. 3A and 3B). Subsequently, a dielectric film made of aluminum oxide is formed on the aluminum foil surface (FIGS. 4A and 4B). The dielectric film may be formed through oxidation of the aluminum foil surfaces or using a film formation method excellent in coverage performance, such as an ALD method, a CVD method, or a mist CVD method. As the material of the dielectric film, TiO₂, Ta₂O₅, or the like may be used in place of Al₂O₃.

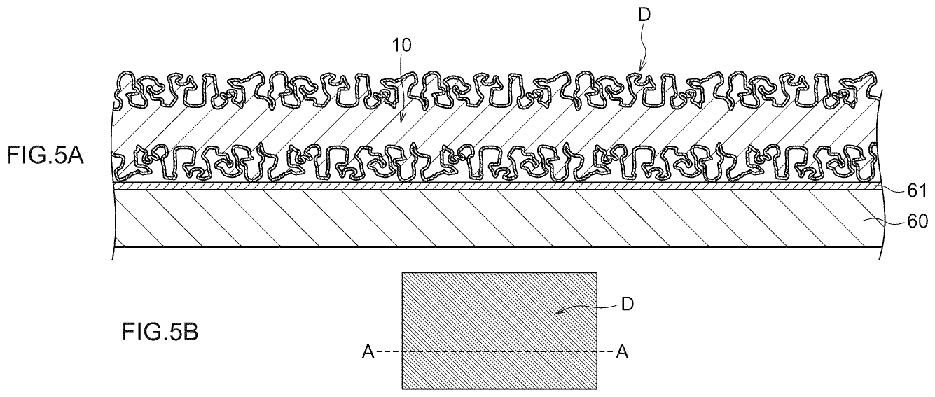

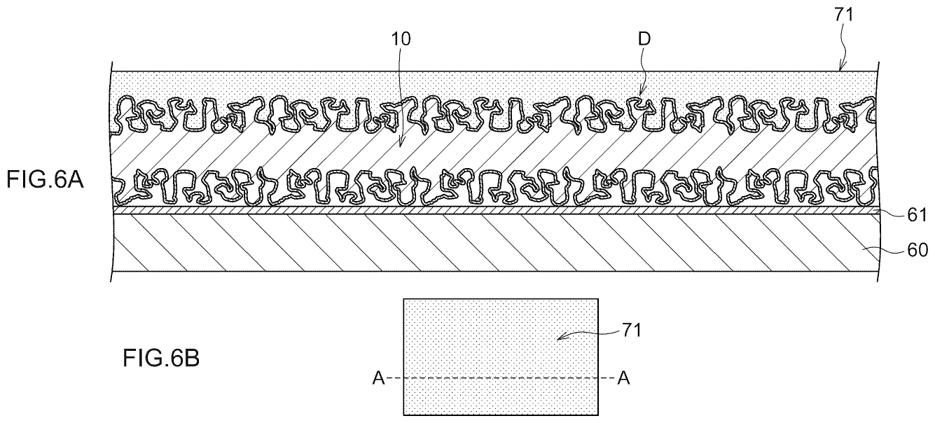

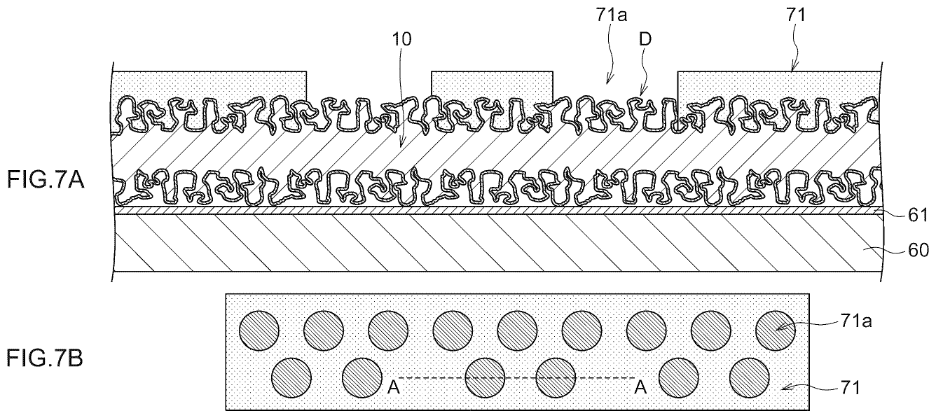

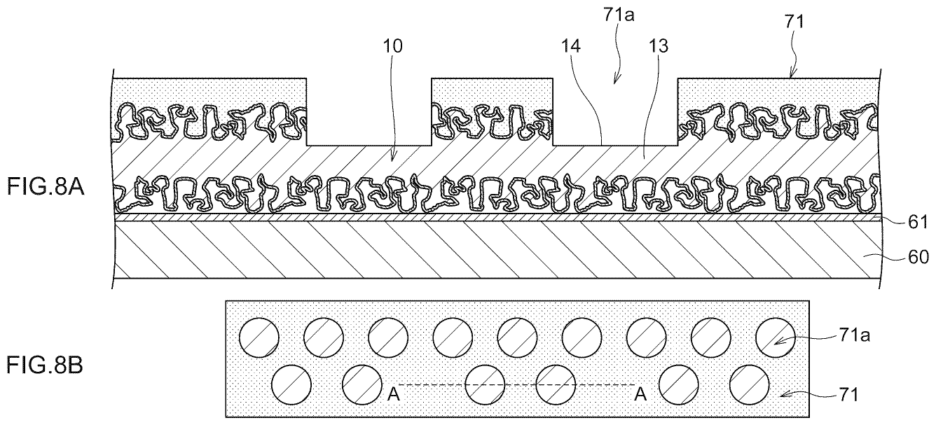

Then, the aluminum foil is placed on a support substrate with an adhesive layer interposed therebetween (FIGS. 5A and 5B), a photosensitive liquid resist is applied onto the surface of the aluminum foil positioned on the side opposite to the support substrate (FIGS. 6A and 6B), followed by exposure and development, whereby the resist is patterned (FIGS. 7A and 7B). Subsequently, the aluminum foil is etched using the resist as a mask to form a groove in the aluminum foil (FIGS. 8A and 8B). At the groove bottom, the non-roughened center part of the aluminum foil is exposed.

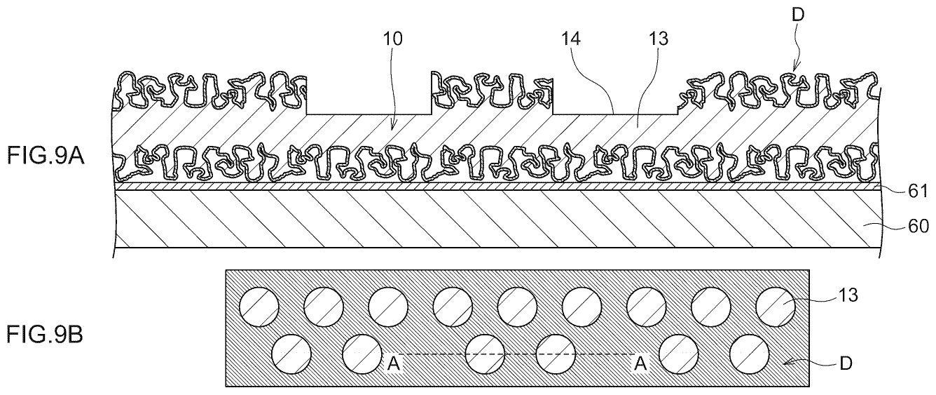

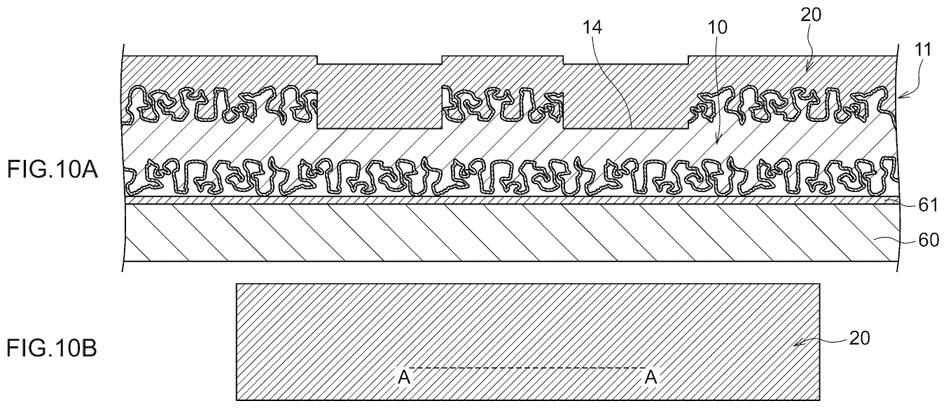

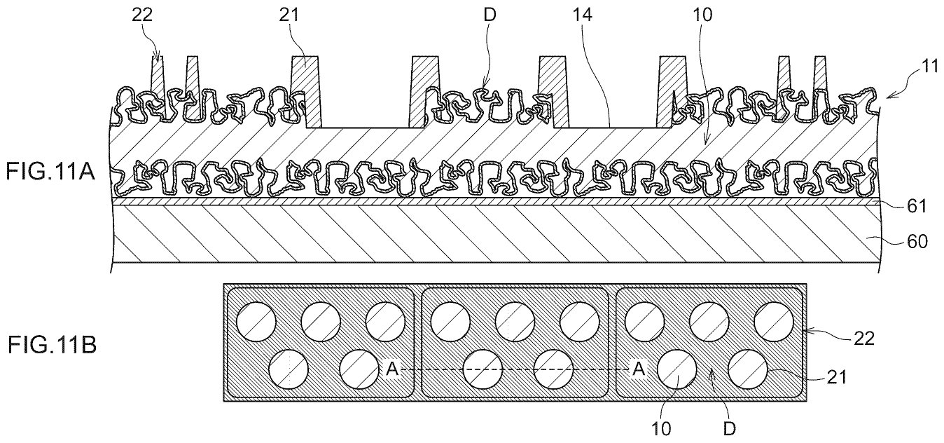

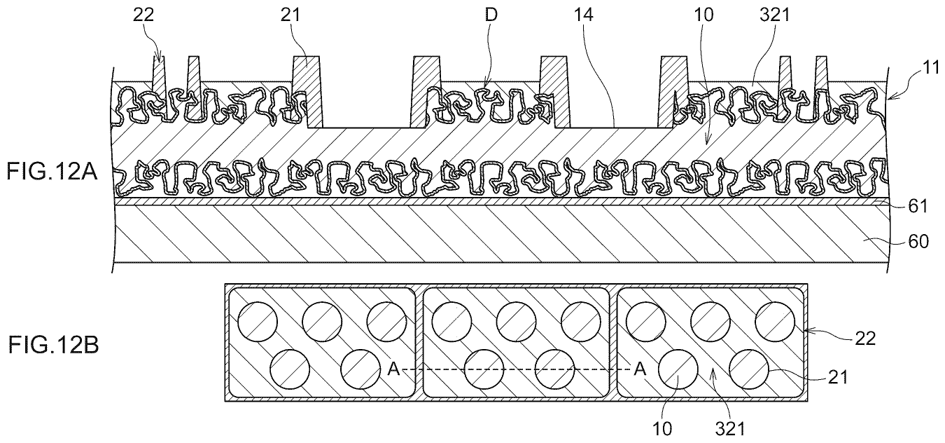

Then, after removal of the resist (FIGS. 9A and 9B), an insulating resin is formed on the upper surface of the aluminum foil (FIGS. 10A and 10B). Subsequently, a not-shown photosensitive resist is formed on the surface of the insulating resin, followed by exposure and development, whereby the insulating resin is patterned (FIGS. 11A and 11B), with the result that the insulating resin is formed into a ring shape. The inner peripheral wall of the ring-shaped insulating resin is preferably positioned within the groove formed in the aluminum foil. The outer peripheral wall of the ring-shaped insulating resin needs to be positioned outside the groove formed in the aluminum foil. Subsequently, a conductive polymer is formed outside the region surrounded by the insulating resin (FIGS. 12A and 12B). The conductive polymer is not formed in the region surrounded by the insulating resin and a portion where the aluminum foil is to be removed for singulation.

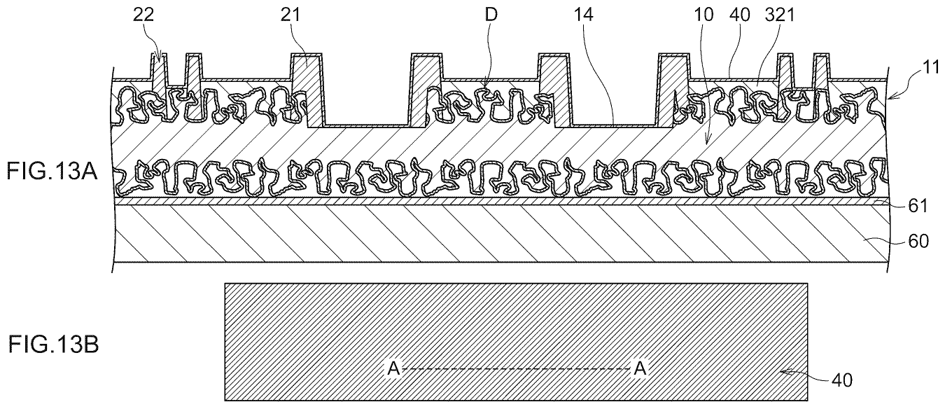

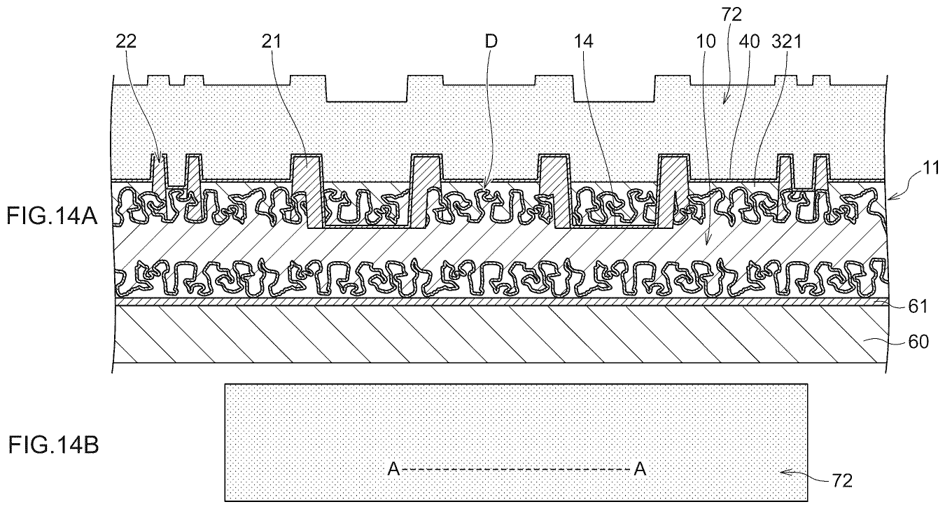

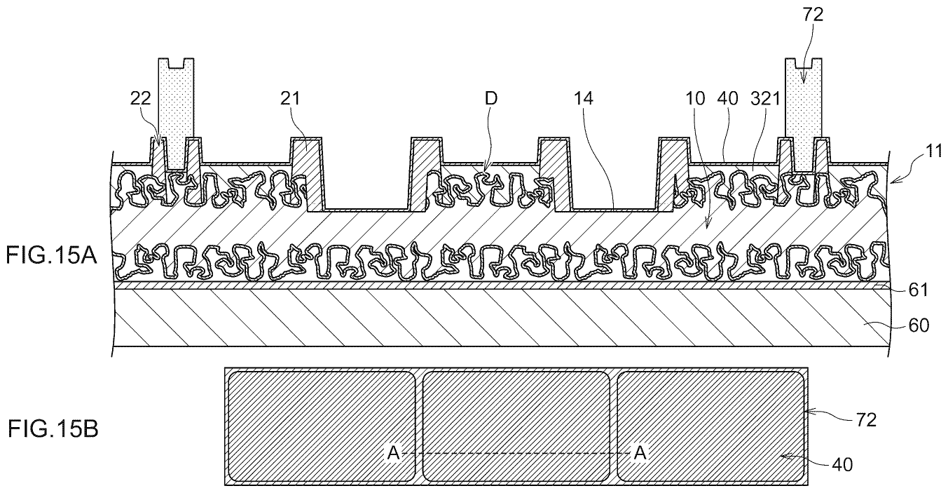

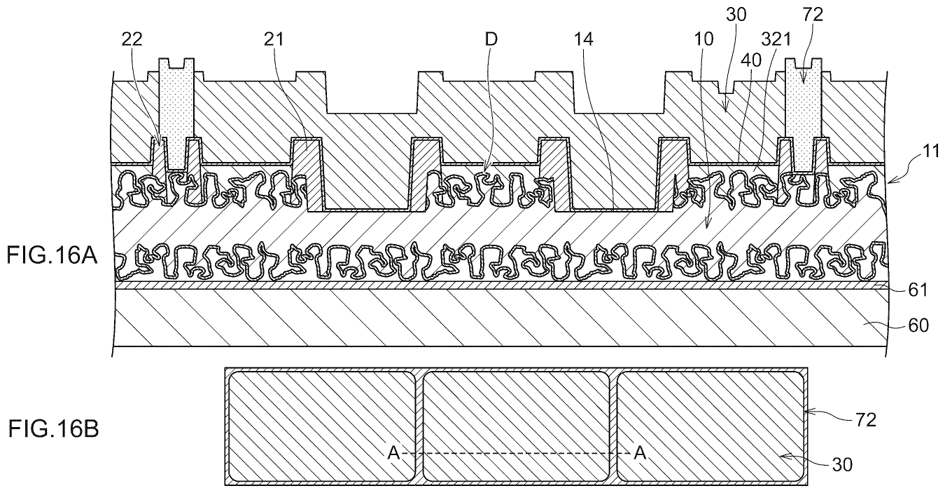

Then, a seed layer is formed on the entire surface using a sputtering method or the like (FIGS. 13A and 13B). Before the seed layer is formed, a residue remaining on the surface may be removed by reverse sputtering. Subsequently, a photosensitive liquid resist is applied onto the entire surface (FIGS. 14A and 14B), followed by exposure and development, whereby the resist is patterned (FIGS. 15A and 15B). As a result, the seed layer corresponding to a single thin film capacitor 1 is exposed. After that, electrolytic plating is performed to form a metal film used as a material for the terminal electrode (FIGS. 16A and 16B).

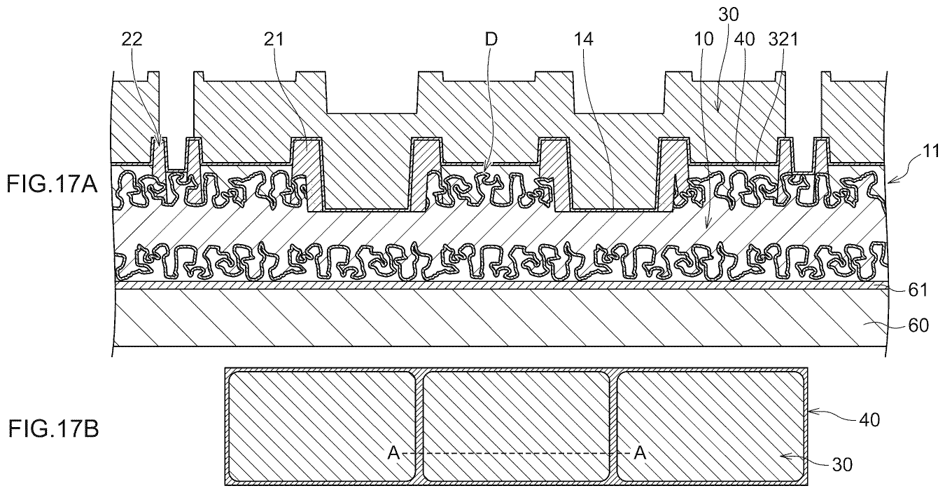

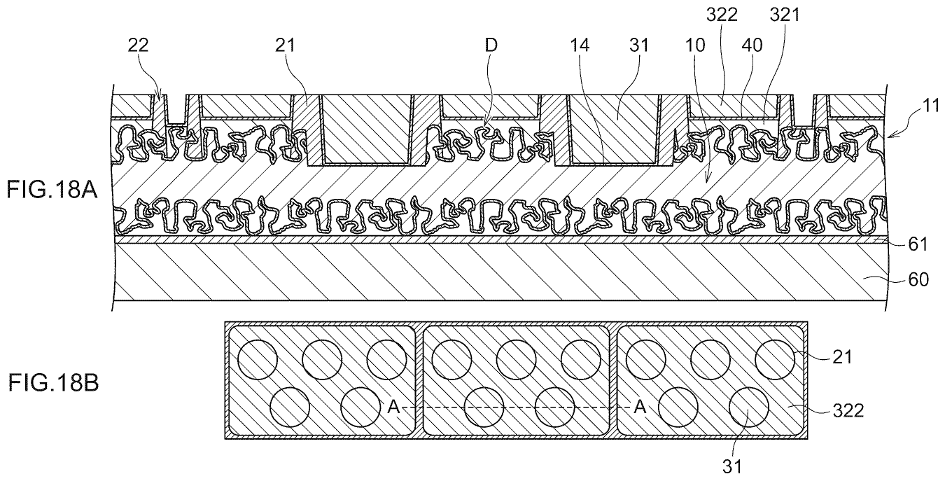

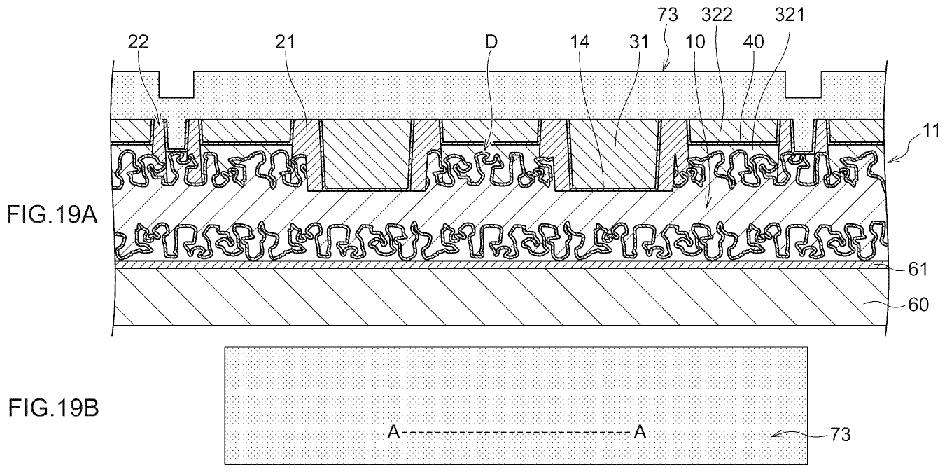

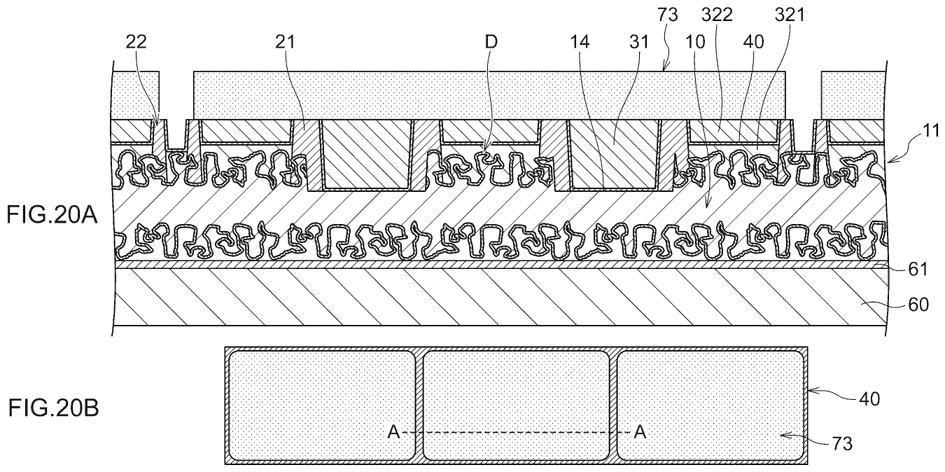

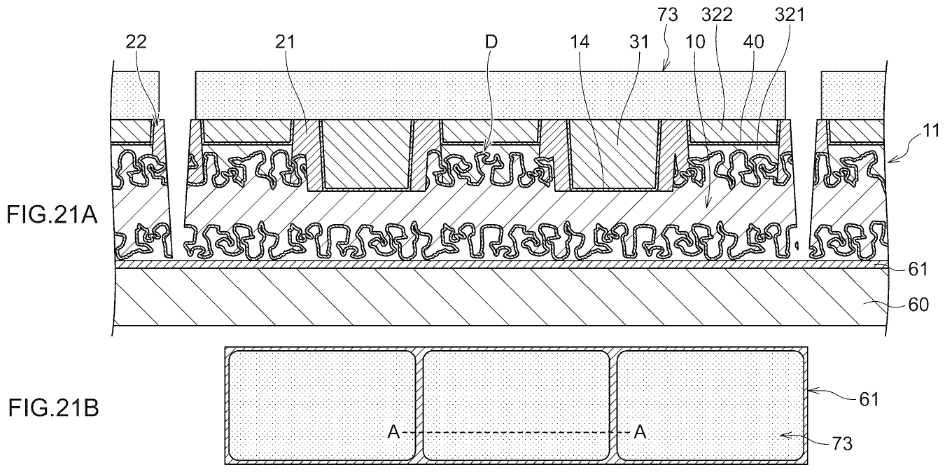

Then, after removal of the resist by ashing or the like (FIGS. 17A and 17B), a CMP is performed to flatten the upper surfaces of the insulating resin and metal film (FIGS. 18A and 18B). This separates the metal film into first and second terminal electrodes. Subsequently, a photosensitive liquid resist is applied onto the entire surface (FIGS. 19A and 19B), followed by exposure and development, whereby the resist is patterned (FIGS. 20A and 20B). Subsequently, the aluminum foil is etched using the resist as a mask to singulate the thin film capacitor (FIGS. 21A and 21B). Subsequently, after removal of the resist by ashing or the like, the support substrate and adhesive layer are removed, whereby the thin film capacitor 1 illustrated in FIGS. 1A and 1B is completed.

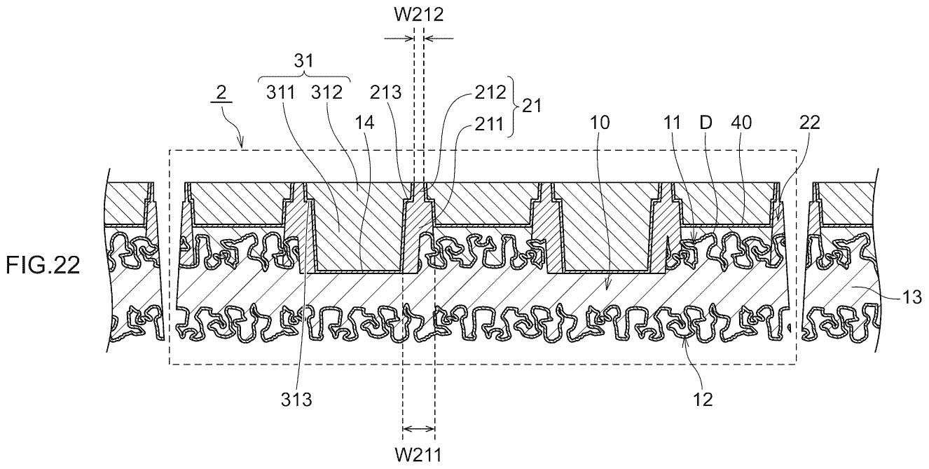

FIG. 22 is a schematic cross-sectional view for explaining the structure of a thin film capacitor 2 according to a second embodiment of the present invention.

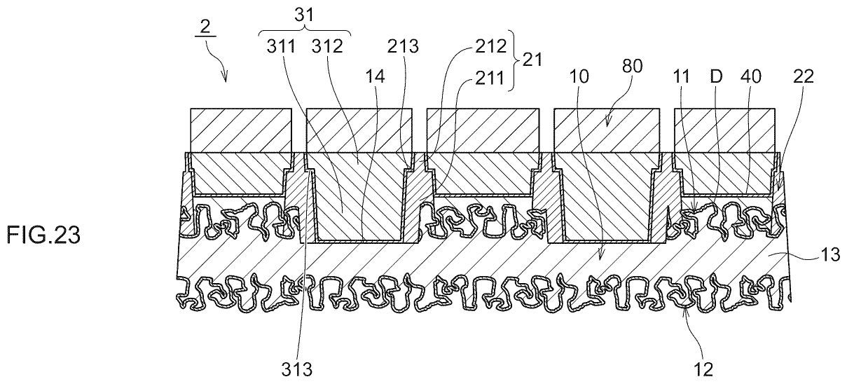

As illustrated in FIG. 22, in the thin-film capacitor 2, the first and second terminal electrodes each have a dual damascene structure. That is, the first and second terminal electrodes each include, in cross section, a lower region with a small diameter and an upper region with a large diameter. A horizontal step surface exists at the boundary between the upper and lower regions. Thus, when the thin-film capacitor 2 is embedded in a multilayer substrate, stress to be applied to the first and second terminal electrodes is distributed, making it hard to apply high stress to the aluminum foil and dielectric film. As illustrated in FIG. 23, the diameter of a via conductor included in the multilayer substrate is preferably larger than the diameter of the lower region of each of the first and second terminal electrodes and smaller than the diameter of the upper region. Further, the edge of the via conductor included in the multilayer substrate preferably overlaps the horizontal step surface positioned at the boundary between the upper and lower regions. Thus, stress to be applied to the first and second terminal electrodes is efficiently distributed by the via conductor, making it harder to apply high stress to the aluminum foil and dielectric film.

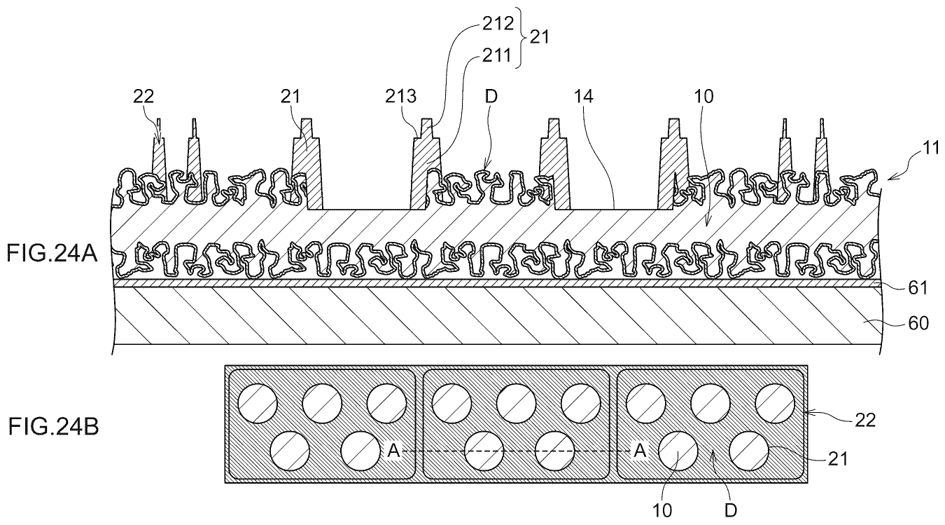

The following describes an example of a manufacturing method for the thin film capacitor 2. FIGS. 24A to 34A are schematic cross-sectional views taken along the line A-A in FIGS. 24B to 34B.

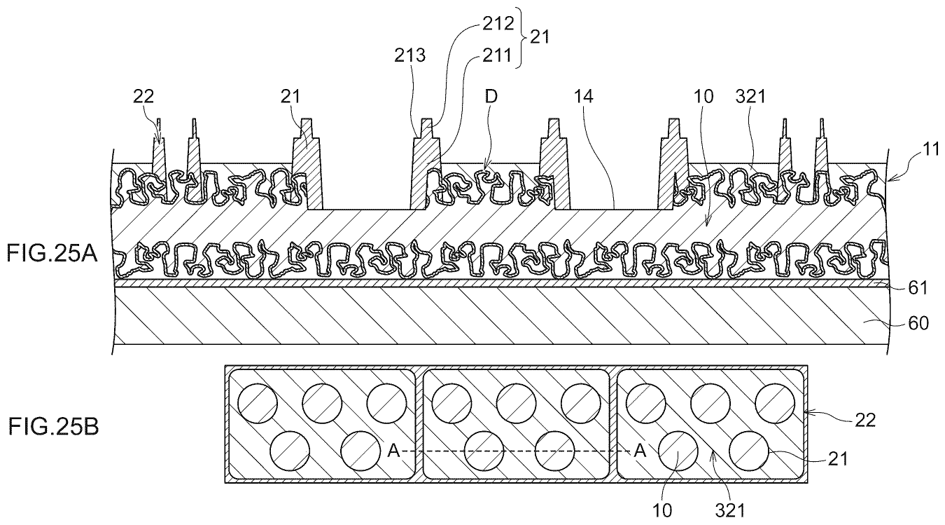

First, after completion of the processes described using FIGS. 2A to 10A, a not-shown photosensitive resist is formed on the surface of the insulating resin, followed by two-step exposure and development, whereby the insulating resin is patterned (FIGS. 24A and 24B). Subsequently, a conductive polymer is formed outside the region surrounded by the insulating resin (FIGS. 25A and 25B). The conductive polymer is not formed in the region surrounded by the insulating resin and a portion where the aluminum foil is to be removed for singulation.

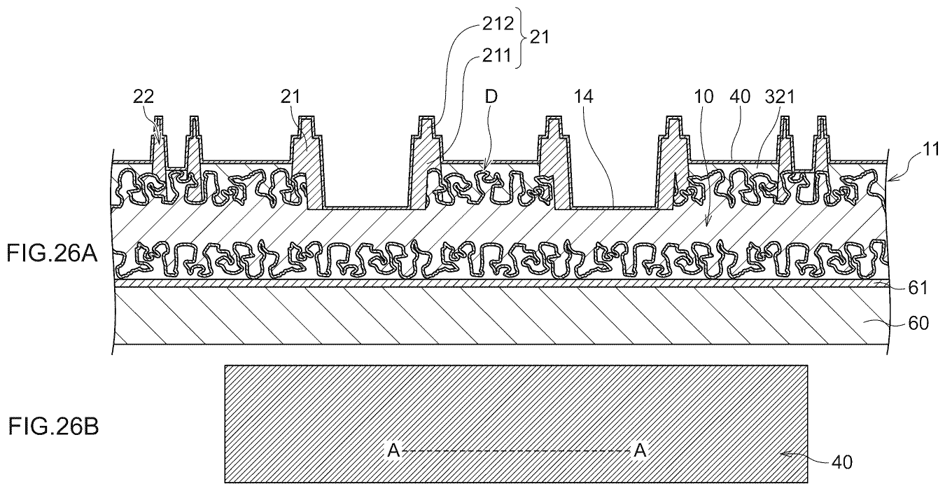

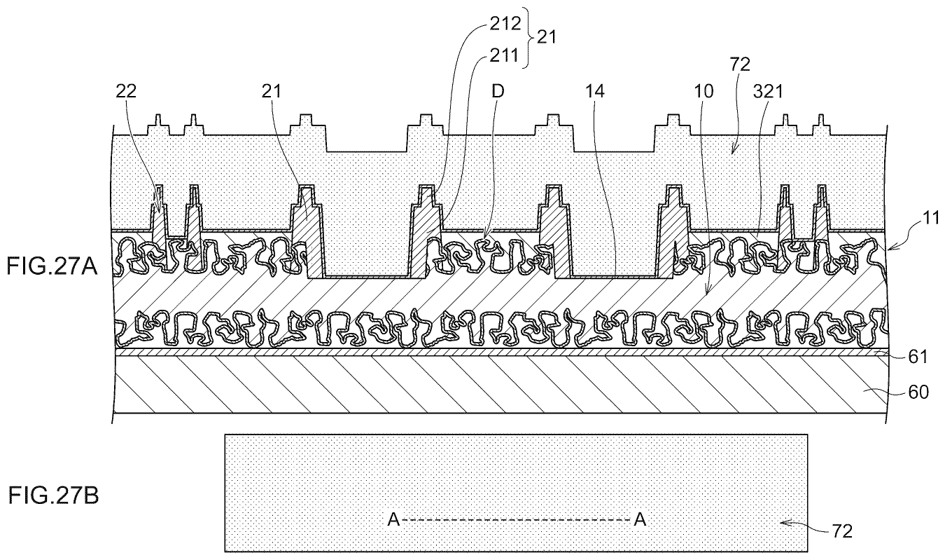

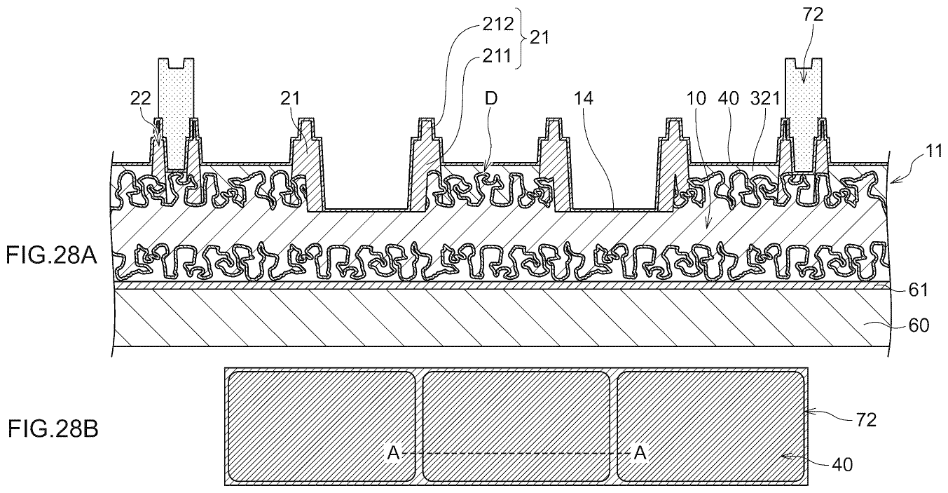

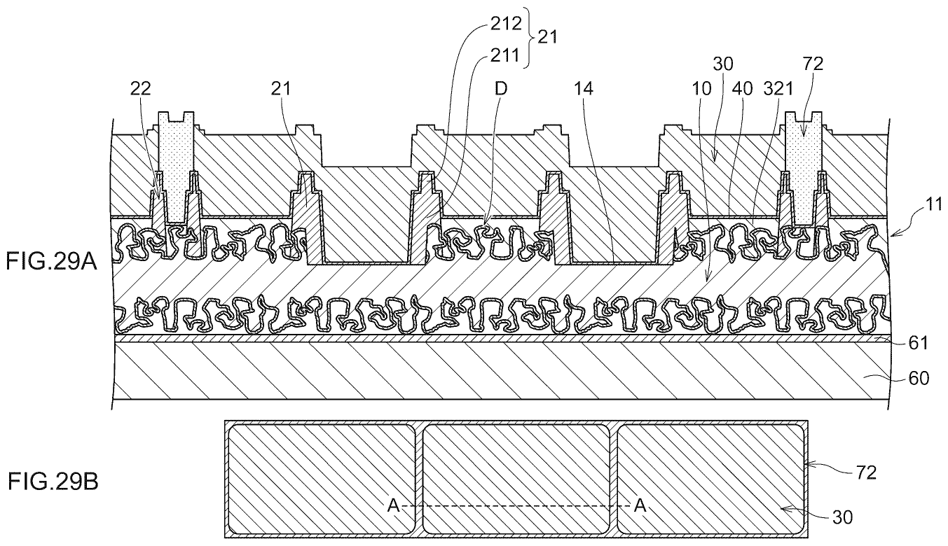

Then, a seed layer is formed on the entire surface using a sputtering method or the like (FIGS. 26A and 26B). Subsequently, a photosensitive liquid resist is applied onto the entire surface (FIGS. 27A and 27B), followed by exposure and development, whereby the resist is patterned (FIGS. 28A and 28B). As a result, the seed layer corresponding to a single thin film capacitor 2 is exposed. After that, electrolytic plating is performed to form a metal film used as a material for the terminal electrode (FIGS. 29A and 29B).

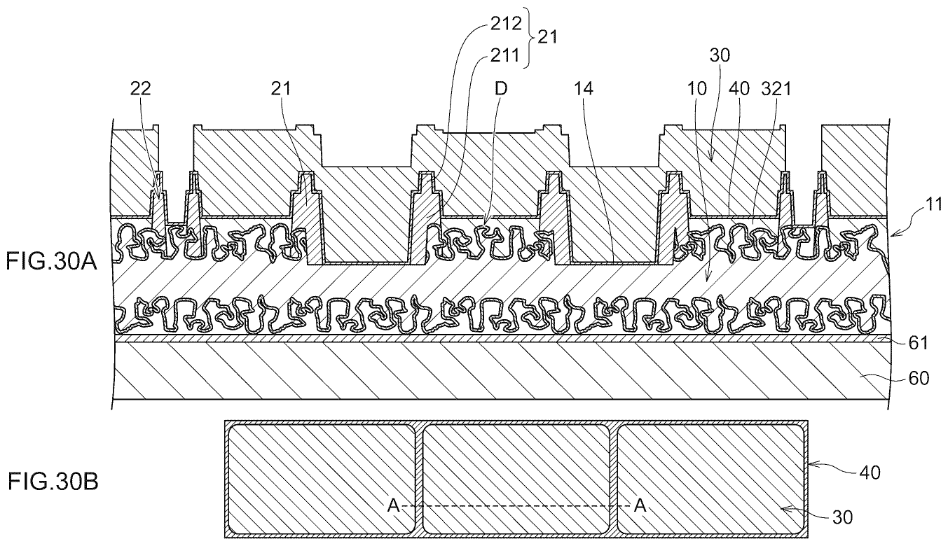

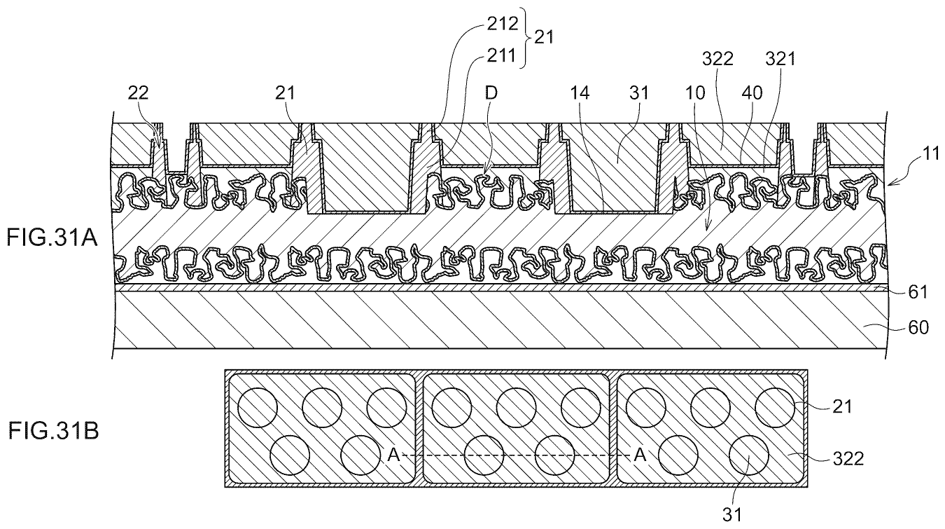

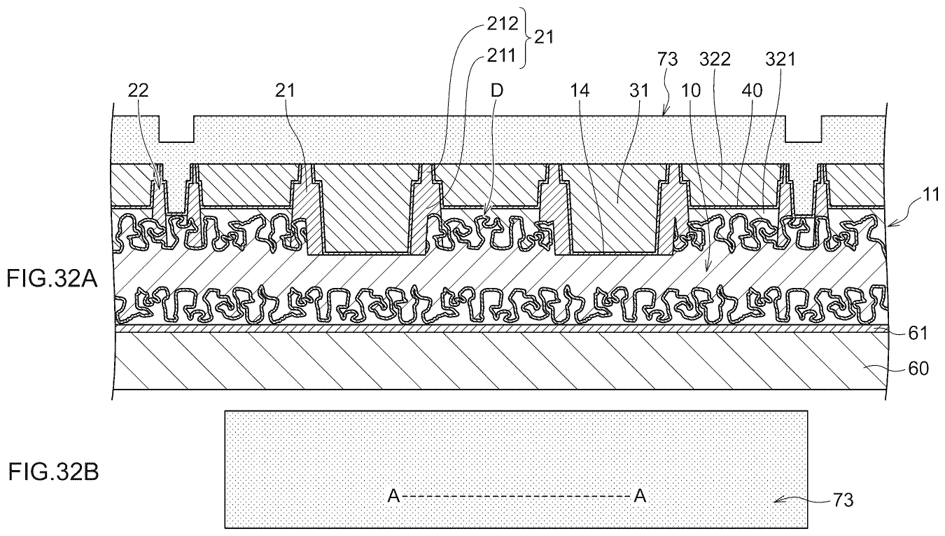

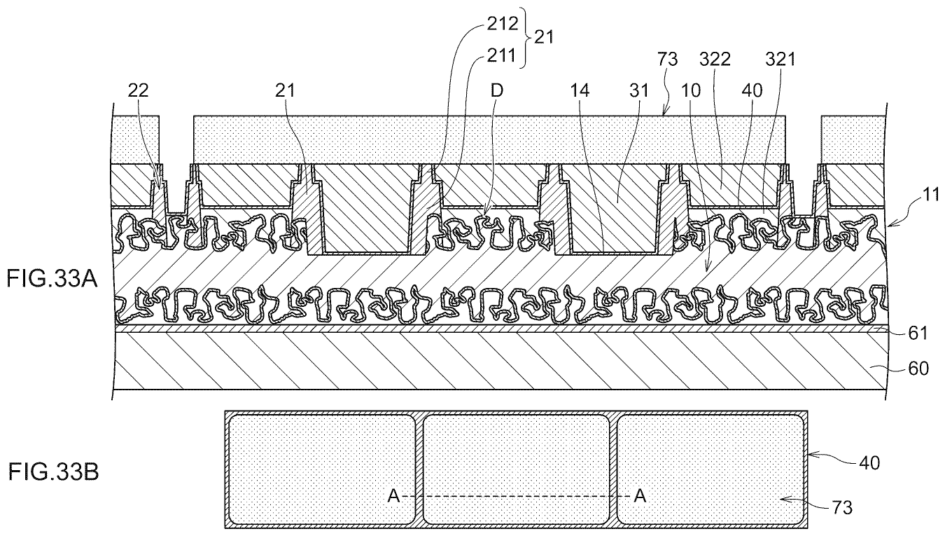

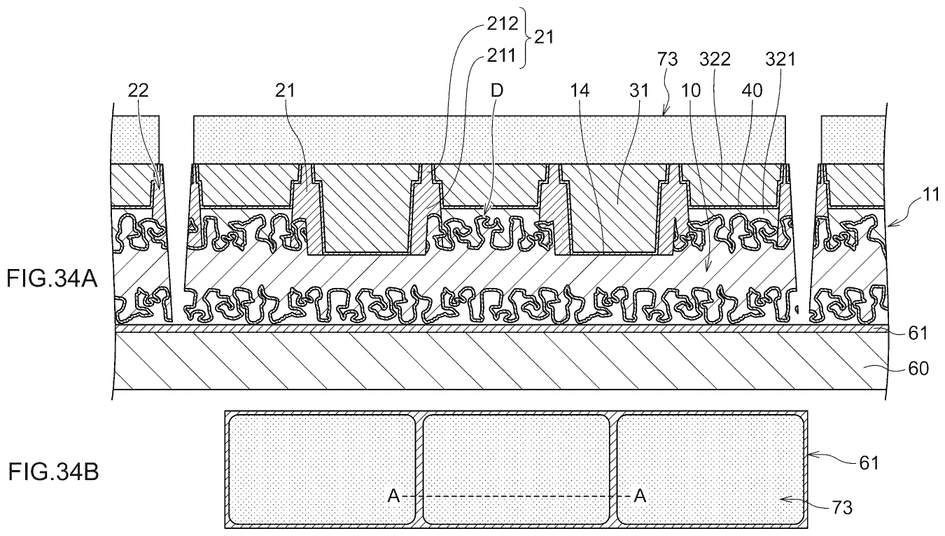

Then, after removal of the resist by ashing or the like (FIGS. 30A and 30B), a CMP is performed to flatten the upper surfaces of the insulating resin and metal film (FIGS. 31A and 31B). This separates the metal film into first and second terminal electrodes. Subsequently, a photosensitive liquid resist is applied onto the entire surface (FIGS. 32A and 32B), followed by exposure and development, whereby the resist is patterned (FIGS. 33A and 33B). Subsequently, the aluminum foil is etched using the resist as a mask to singulate the thin film capacitor (FIGS. 34A and 34B). Subsequently, after removal of the resist by ashing or the like, the support substrate and adhesive layer are removed, whereby the thin film capacitor 2 illustrated in FIG. 22 is completed.

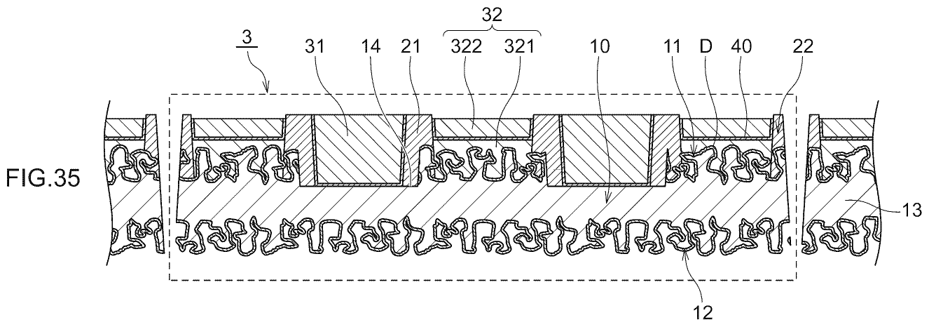

FIG. 35 is a schematic cross-sectional view for explaining the structure of a thin film capacitor 3 according to a third embodiment of the present invention.

As illustrated in FIG. 35, in the thin-film capacitor 3, the upper surface position of the second terminal electrode is lower than the upper surface position of the first terminal electrode. The upper surface of the first terminal electrode and the upper surface of the insulating resin are substantially flush with each other. Thus, when the thin film capacitor 3 is embedded in a multilayer substrate, stress is less likely to be applied to the second terminal electrode, which makes the reduction in capacitance and short-circuit failure less likely to occur. Such a structure can be obtained by applying the CMP to the metal film on condition that a polishing rate is higher for the second terminal electrode having a larger area than for the first terminal electrode having a smaller area.

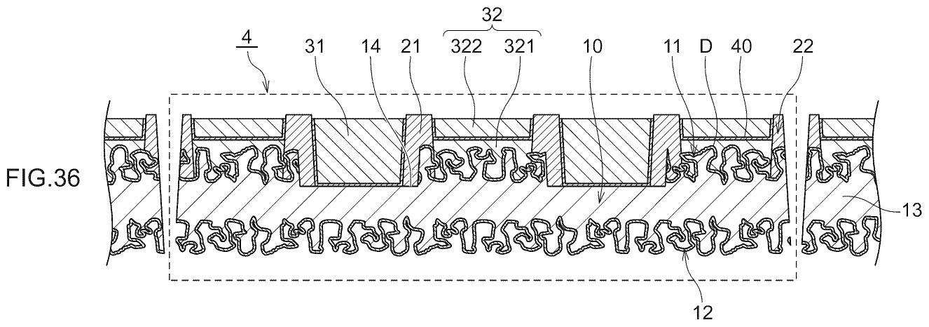

FIG. 36 is a schematic cross-sectional view for explaining the structure of a thin film capacitor 4 according to a fourth embodiment of the present invention.

As illustrated in FIG. 36, in the thin-film capacitor 4, the upper surface positions of the first and second terminal electrodes are lower than the upper surface position of the insulating resin. The upper surface of the first terminal electrode and the upper surface of the second terminal electrode are substantially flush with each other. Thus, when the thin film capacitor 4 is embedded in a multilayer substrate, stress is less likely to be applied to the first and second terminal electrodes. Such a structure can be obtained by applying the CMP to the metal film on condition that a polishing rate is higher for the metal film than for the insulating resin.

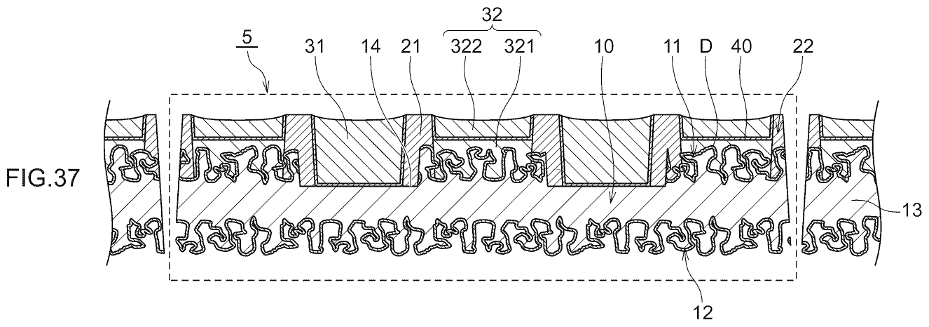

FIG. 37 is a schematic cross-sectional view for explaining the structure of a thin film capacitor 5 according to a fifth embodiment of the present invention.

As illustrated in FIG. 37, in the thin-film capacitor 5, the upper surfaces of the first and second terminal electrodes are recessed. In other words, the upper surfaces of the first and second terminal electrodes are reduced in height with increasing distance from the insulating resin. This makes the first and second terminal electrodes unlikely to be peeled. Further, when the thin-film capacitor 5 is embedded in a multilayer substrate, stress is less likely to be applied to the first and second terminal electrodes. Such a structure can be obtained by applying the CMP to the metal film on condition that a polishing rate is higher for the metal film than for the insulating resin.

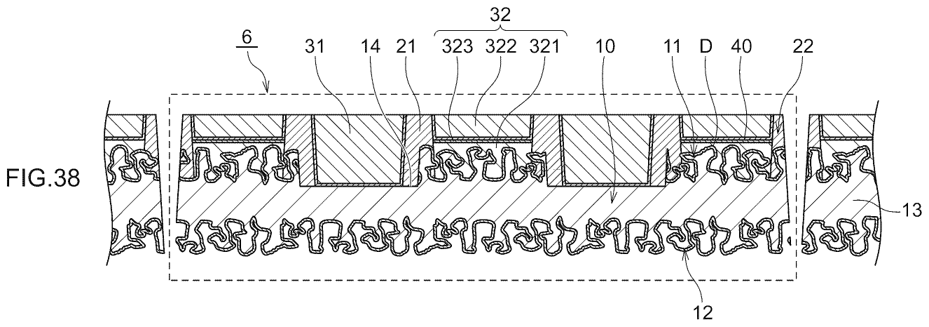

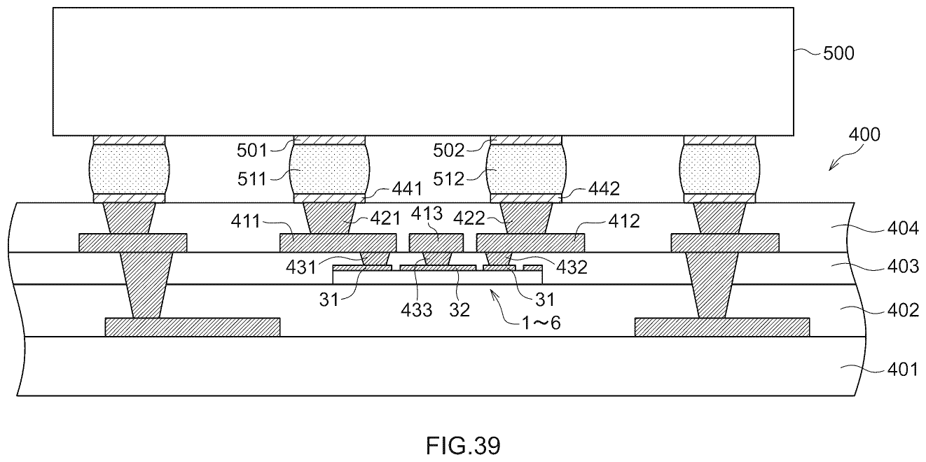

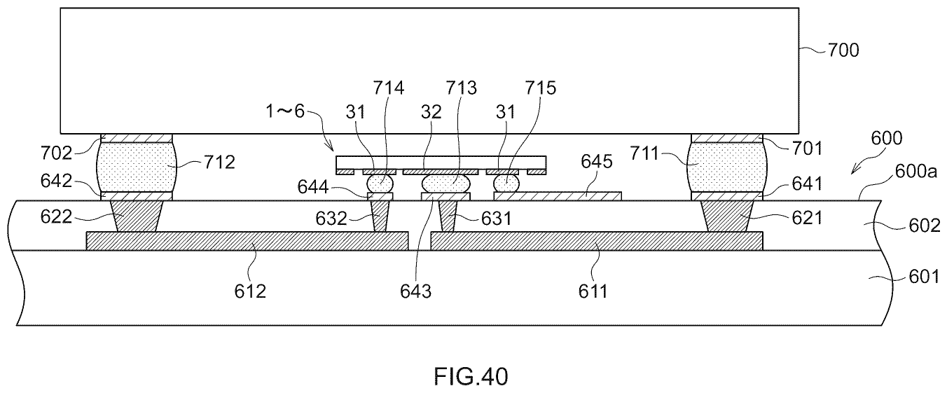

FIG. 38 is a schematic cross-sectional view for explaining the structure of a thin film capacitor 6 according to a sixth embodiment of the present invention.

As illustrated in FIG. 38, in the thin-film capacitor 6, a conductive adhesion layer is provided between the second terminal electrode and the conductive polymer. The conductive adhesion layer acts to enhance adhesion between the second terminal electrode and the conductive polymer, whereby the second terminal electrode is unlikely to be peeled. As the material of the conductive adhesion layer, TiC or TaC may be used. The conductive adhesion layer may be a composite film of a TiC film and a TaC film or a composite film of a carbon film, a WC film, and a Cr film.

1. A thin film capacitor comprising:
a metal foil having a roughened surface;
a dielectric film covering the roughened surface of the metal foil and having an opening partially exposing the metal foil therethrough;
a first electrode layer contacting the metal foil through the opening; and
a second electrode layer contacting the dielectric film without contacting the metal foil,
wherein an upper surface position of the second electrode layer is equal to or lower in height than an upper surface position of the first electrode layer.

2. The thin film capacitor as claimed in claim 1, further comprising an insulating member positioned between the first and second electrode layers,
wherein the upper surface position of the second electrode layer is equal to or lower in height than an upper surface position of the insulating member.

3. A thin film capacitor comprising:
a metal foil having a roughened surface;
a dielectric film covering the roughened surface of the metal foil and having an opening partially exposing the metal foil therethrough;
a first electrode layer contacting the metal foil through the opening;
a second electrode layer contacting the dielectric film without contacting the metal foil; and
an insulating member positioned between the first and second electrode layers,
wherein an upper surface position of the second electrode layer is equal to or lower in height than an upper surface position of the insulating member.

4. The thin film capacitor as claimed in claim 2, wherein the upper surface of the second electrode layer has a recessed shape reducing in height with distance from the upper surface of the insulating member.

5. The thin film capacitor as claimed in claim 2, wherein an upper surface position of the first electrode layer is lower in height than the upper surface position of the insulating member.

6. The thin film capacitor as claimed in claim 5, wherein the upper surface of the first electrode layer has a recessed shape reducing in height with distance from the upper surface of the insulating member.

7. The thin film capacitor as claimed in claim 2, wherein the insulating member has a lower insulating region contacting the dielectric film and having a first width between the first and second electrode layers and an upper insulating region positioned on the lower insulating region and having a second width between the first and second electrode layers smaller than the first width to make the first and second electrode layers have a dual damascene structure.

8. The thin film capacitor as claimed in claim 1, wherein the second electrode layer includes a first conductive member contacting the dielectric film and made of a conductive polymer material and a second conductive member connected to the first conductive member and made of a metal material.

9. The thin film capacitor as claimed in claim 8, wherein the second electrode layer further includes a close-contact layer positioned between the first and second conductive members.

10. The thin film capacitor as claimed in claim 9, wherein the close-contact layer is made of a TiC film, a TaC film, a composite film of the TiC film and TaC film, or a composite film of a carbon film, a WC film, and a Cr film.

11. An electronic circuit board comprising:
a substrate having a wiring pattern;
a semiconductor IC and the thin film capacitor as claimed in claim 1 each provided in the substrate,
wherein the first and second electrode layers of the thin film capacitor are connected to the semiconductor IC through the wiring pattern.

12. An electronic circuit board comprising:
a substrate having a wiring pattern;
a semiconductor IC and the thin film capacitor as claimed in claim 7 each provided in the substrate,
wherein the thin film capacitor is embedded in the substrate,
wherein the insulating member has an annular structure surrounding the first electrode,
wherein the first electrode layer has a lower electrode region surrounded by the lower insulating region of the insulating member and an upper electrode region surrounded by the upper insulating region of the insulating member,
wherein the substrate further has a via conductor connecting the wiring pattern and first electrode layer, and
wherein the via conductor has a diameter larger than that of the lower electrode region of the first electrode layer.
